(19) United States
(12) Patent Application Publication
(10) Pub. No.: US 2026/0243840 A1
(43) Pub. Date: Aug. 20, 2026

(54) APPARATUS AND METHOD FOR DIAGNOSING BATTERY CELL DETERIORATION

(71) Applicants: HYUNDAI MOTOR COMPANY, Seoul (KR); KIA CORPORATION, Seoul (KR)

(72) Inventors: Yo Han Baek, Hwaseong-si (KR); Hyo Kyung Lee, Hwaseong-si (KR); Bo Hyun Lee, Hwaseong-si (KR)

(73) Assignees: HYUNDAI MOTOR COMPANY, Seoul (KR); KIA CORPORATION, Seoul (KR)

(21) Appl. No.: 19/261,699

(22) Filed: Jul. 7, 2025

(30) Foreign Application Priority Data
Feb. 19, 2025 (KR) 10-2025-0021717

(51) Int. Cl. G01R 31/392; G01R 31/367; G01R 31/3842; G01R 31/396; H01M 10/44; H01M 10/48

(52) U.S. Cl. CPC G01R 31/392; G01R 31/367; G01R 31/3842; G01R 31/396; H01M 10/441; H01M 10/482

(57) ABSTRACT

An apparatus for diagnosing battery cell deterioration includes a memory that stores a frequency distribution table, and a processor configured to diagnose the battery cell deterioration based on the frequency distribution table. The processor is configured to determine a cell voltage representative value for a battery pack for which deterioration is to be diagnosed, generate the frequency distribution table based on battery cell voltage and current data corresponding to charging or discharging of the battery pack, store the frequency distribution table in the memory, preprocess the frequency distribution table to determine a valid data range, and diagnose the battery cell deterioration based on a frequency within the valid data range.

### CROSS-REFERENCE TO RELATED APPLICATION

This application claims the benefit of and priority to Korean Patent Application No. 10-2025-0021717, filed on Feb. 19, 2025, the entire contents of which are hereby incorporated herein by reference.

### TECHNICAL FIELD

The present disclosure relates to an apparatus and a method for diagnosing battery cell deterioration.

### BACKGROUND

The statements in this section merely provide background information related to the present disclosure and may not constitute prior art.

Battery cell-level deterioration diagnostic information is used in various applications such as certified used vehicles and battery certificate issuance.

However, the current deterioration diagnosis scheme may only utilize state of health (SOH) information at the battery pack level.

This is because the resolution of cell voltage data obtained from vehicle on-board diagnostics (OBD) or a removed battery system assembly (BSA) is low, making it difficult to calculate SOH for each cell based on low-resolution data.

When calculating SOH with low-resolution data, large errors may occur.

For example, when calculating SOH, a controller in a vehicle uses high-resolution (1 mV) data, so when calculating with low-resolution (20 mV) data, a large error is unavoidable.

However, in order to obtain high-resolution data from a vehicle, damage to components within the vehicle may be inevitable and additional labor may be incurred.

For example, in order to obtain high-resolution data, damage to components may occur, such as cutting of a wire harness insulation cover, cutting of a braided wire, and damage to the covering due to a CAN communication line probe, and additional labor may occur, such as requiring a software tool (S/W Tool) for data analysis for research and development, a driving PC, and a ROM file matching a vehicle firmware (F/W).

### SUMMARY

The present disclosure has been made to solve the above-mentioned problems occurring in the prior art while advantages achieved by the prior art are maintained intact.

Aspects of the present disclosure provide an apparatus and a method for diagnosing battery cell deterioration that are capable of precisely diagnosing the deterioration status of each battery cell without damage to vehicle components or additional labor even in a system with low voltage resolution. The apparatus and the method may generate a frequency distribution table in which a current change amount by class section that divides the voltage range of a battery cell is expressed as a frequency, may obtain a valid data range, and may diagnose battery cell deterioration based on the sum of frequencies of each battery cell by adding up the frequencies within the valid data range.

The technical problems to be solved by the present disclosure are not limited to the aforementioned problems. Other technical problems not mentioned herein should be more clearly understood from the following description by those having ordinary skill in the art to which the present disclosure pertains.

According to an aspect of the present disclosure, an apparatus for diagnosing battery cell deterioration is provided. The apparatus include a memory configured to store a frequency distribution table, and a processor configured to diagnose the battery cell deterioration based on the frequency distribution table. The processor is configured to determine a cell voltage representative value for a battery pack for which deterioration is to be diagnosed. The processor is also configured to generate the frequency distribution table based on battery cell voltage and current data corresponding to charging or discharging of the battery pack. The processor is additionally configured to store the frequency distribution table in the memory, preprocess the frequency distribution table to determine a valid data range, and diagnose the battery cell deterioration based on a frequency within the valid data range.

According to an embodiment, the processor may be configured to determine a cell deterioration diagnosis mode corresponding to the discharging or charging when a battery cell deterioration diagnosis execution request is received while calculating the cell voltage representative value, calculate the cell voltage representative value for the battery pack, store the cell voltage representative value at a starting time point in the memory, and perform the discharging or charging of the battery pack corresponding to the determined cell deterioration diagnosis mode.

According to an embodiment, the processor may be configured to obtain voltage and current data for each battery cell corresponding to the discharging or charging of the battery pack when generating the frequency distribution table and performing the discharging or charging of the battery pack, store the voltage and current data in the memory, perform a clustered frequency distribution by dividing a voltage range of the battery cell into class sections of a preset size based on the voltage and current data of each battery cell, and generate a frequency distribution table in which a current change amount of each class section for each battery cell is expressed as a frequency.

According to an embodiment, the processor may be configured to obtain a high-resolution valid data range by performing a non-clustered frequency distribution through a preprocess of removing a frequency of a first class section and a frequency of a last class from the frequency distribution table when obtaining the valid data range.

According to an embodiment, the processor may be configured to remove voltage data at a time point when the discharging or charging starts, voltage data before the time point when the discharging or charging starts, voltage data at a time point when the discharging or charging ends, and voltage data after the time point when the discharging or charging ends, based on the voltage data for each battery cell. The processor may be configured to obtain the high-resolution valid data range including voltage data from the time point at which the discharging or charging starts to the time point at which the discharging or charging ends.

According to an embodiment, the processor may be configured to integrate a plurality of classes within the valid data range into one class by adding up frequencies classified by class within the valid data range when diagnosing the deterioration of each battery cell. The processor may be configured to calculate a sum of the frequencies for each battery cell and store the sum in the memory.

According to an embodiment, the processor may be configured to calculate a deterioration degree of each battery cell through a proportional formula based on a deterioration degree and a frequency value corresponding to the cell voltage representative value and the sum of the frequencies of each battery cell when diagnosing the deterioration of each battery cell, and diagnose the deterioration of the battery cell based on the calculated deterioration degree of each battery cell.

According to another aspect of the present disclosure, a method of diagnosing battery cell deterioration is provided. The method includes determining, by a processor, a cell voltage representative value for a battery pack for which deterioration is to be diagnosed. The method also includes generating, by the processor, a frequency distribution table based on battery cell voltage and current data corresponding to charging or discharging of the battery pack. The method additionally includes preprocessing, by the processor, the frequency distribution table to obtain a valid data range. The method further includes diagnosing, by the processor, the battery cell deterioration based on a frequency within the valid data range.

### BRIEF DESCRIPTION OF THE DRAWINGS

The above and other objects, features, and advantages of the present disclosure should become more apparent from the following detailed description taken in conjunction with the accompanying drawings, in which:

FIG. 1 is a diagram illustrating a process of diagnosing battery cell deterioration by an apparatus for diagnosing battery cell deterioration, according to an embodiment of the present disclosure;

FIG. 2 is a block diagram illustrating the configuration of an apparatus for diagnosing battery cell deterioration, according to an embodiment of the present disclosure;

FIGS. 3A to 3C are diagrams illustrating a high-resolution data acquisition principle of an apparatus for diagnosing battery cell deterioration, according to an embodiment of the present disclosure;

FIGS. 4 and 5 are diagrams illustrating a preprocessing process for obtaining high-resolution data by an apparatus for diagnosing battery cell deterioration, according to an embodiment of the present disclosure;

FIG. 6 is a flowchart illustrating a method of diagnosing battery cell deterioration, according to an embodiment of the present disclosure;

FIGS. 7-10 are diagrams illustrating a process of diagnosing battery cell deterioration based on a frequency distribution table by an apparatus for diagnosing battery cell deterioration, according to an embodiment of the present disclosure;

FIGS. 11 and 12 are flowcharts illustrating in detail a method of diagnosing vehicle battery cell deterioration, according to one embodiment of the present disclosure;

FIGS. 13-15 are graphs illustrating the results of diagnosing vehicle battery cell deterioration, according to an embodiment of the present disclosure; and

FIG. 16 is a block diagram illustrating a computing system of a vehicle, according to an embodiment of the present disclosure.

### DETAILED DESCRIPTION

Hereinafter, embodiments of the present disclosure are described in detail with reference to the accompanying drawings. In adding the reference numerals to the components of each drawing, it should be noted that the identical or equivalent components are designated by the identical numeral even when the components are displayed on different drawings. Further, in the present disclosure, where it was determined that a detailed description of the related known configuration or function would obscure the gist of the present disclosure, the detailed description thereof has been omitted.

In addition, terms, such as first, second, A, B, (a), (b) or the like may be used herein when describing components of the present disclosure. The terms are provided only to distinguish the elements from other elements, and the essences, sequences, orders, and numbers of the elements are not limited by the terms. In addition, unless defined otherwise, all terms used herein, including technical or scientific terms, have the same meanings as those generally understood by those having ordinary skill in the art to which the present disclosure pertains. The terms defined in the generally used dictionaries should be construed as having the meanings that coincide with the meanings of the contexts of the related technologies, and should not be construed as ideal or excessively formal meanings unless clearly defined in the specification of the present disclosure.

In the present disclosure, when a component, controller, device, element, apparatus, unit or the like of the present disclosure is described as having a purpose or performing an operation, function, or the like, the component, controller, device, element, apparatus, unit or the like should be considered herein as being “configured to” meet that purpose or to perform that operation or function. Each component, controller, device, element, apparatus, unit, server, and the like may separately embody or be included with a processor and a memory, such as a non-transitory computer readable media, as part of the apparatus.

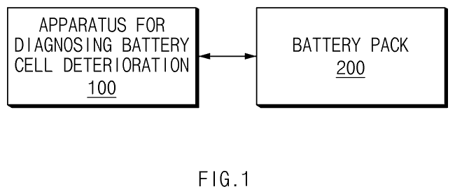

Hereinafter, embodiments of the present disclosure are described in detail with reference to FIGS. 1-16.

FIG. 1 is a diagram illustrating a process of diagnosing battery cell deterioration by an apparatus for diagnosing battery cell deterioration according to an embodiment of the present disclosure.

As illustrated in FIG. 1, an apparatus 100 for diagnosing battery cell deterioration according to an embodiment of the present disclosure may diagnose deterioration of each battery cell of a battery pack 200 of a vehicle.

In an embodiment, the apparatus 100 may calculate or otherwise determine a cell voltage representative value for the battery pack 200 for which deterioration is to be diagnosed and may generate a frequency distribution table, in which the current change amount of each class section into which the voltage range of the battery cell is divided is expressed as a frequency, based on battery cell voltage and current data corresponding to charging or discharging of the battery pack 200. The apparatus 100 may also preprocess the frequency distribution table to obtain a valid data range, may calculate a sum of the frequencies for each battery cell by adding up the frequencies within a valid data range, may calculate a deterioration degree and a frequency value corresponding to a cell voltage representative value, and may diagnose the battery cell deterioration based on the deterioration degree and the frequency value corresponding to the cell voltage representative value and the sum of the frequencies for each battery cell.

In addition, when a battery cell deterioration diagnosis execution request is received while calculating the cell voltage representative value, the apparatus 100 may determine a cell deterioration diagnosis mode corresponding to the discharging or charging, may calculate the cell voltage representative value for the battery pack 200, store the cell voltage representative value at a starting time point, and may perform the discharging or charging of the battery pack 200 corresponding to the determined cell deterioration diagnosis mode.

In addition, when the frequency distribution table is generated while the discharging or charging of the battery pack is performed, the apparatus 100 may obtain voltage and current data for each battery cell corresponding to the discharging or charging of the battery pack 200, may perform a clustered frequency distribution by dividing a voltage range of the battery cell into class sections of a preset size based on the voltage and current data of each battery cell, and may generate a frequency distribution table in which a current change amount of each class section for each battery cell is expressed as a frequency.

In addition, when the valid data range is obtained, the apparatus 100 may obtain a high-resolution valid data range by performing a non-clustered frequency distribution through a preprocess of removing a frequency of a first class section and a frequency of a last class section from the frequency distribution table.

In an embodiment, the apparatus 100 may remove voltage data at a time point when the discharging or charging starts, voltage data before the time point when the discharging or charging starts, voltage data at a time point when the discharging or charging ends, and voltage data after the time point when the discharging or charging ends, based on the voltage data for each battery cell. The apparatus 100 may obtain the high-resolution valid data range including voltage data from the time point at which the discharging or charging starts to the time point at which the discharging or charging ends.

In addition, when the sum of frequencies is calculated, the apparatus 100 may integrate a plurality of classes within the valid data range into one class by adding up frequencies classified by class within the valid data range for each battery cell, thereby obtaining the sum of frequencies for each battery cell.

In addition, when diagnosing the deterioration of each battery cell, the apparatus 100 may calculate a deterioration degree of each battery cell through a proportional formula based on a deterioration degree and a frequency value corresponding to the cell voltage representative value and the sum of the frequencies of each battery cell, and may diagnose the deterioration of the battery cell based on the calculated deterioration degree of each battery cell.

According to embodiments of the present disclosure, by generating the frequency distribution table in which the current change amount by class section that divides the voltage range of the battery cell is expressed as a frequency, obtaining the valid data range, and diagnosing battery cell deterioration based on the sum of the frequencies of each battery cell by adding up the frequencies within the valid data range, it is possible to precisely diagnose the deterioration status of each battery cell without damage to vehicle parts or additional labor in a system with low voltage resolution.

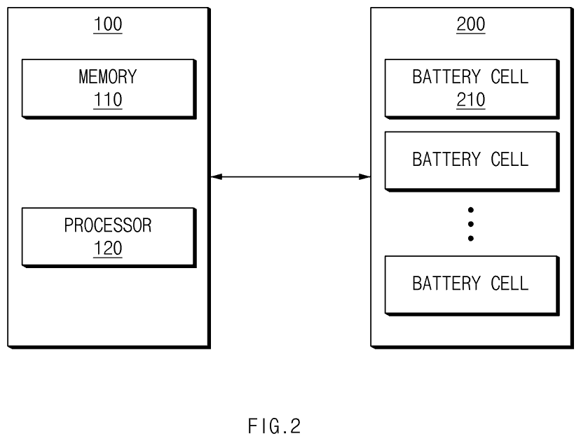

FIG. 2 is a block diagram illustrating the configuration of an apparatus for diagnosing battery cell deterioration according to an embodiment of the present disclosure.

As illustrated in FIG. 2, the apparatus 100 for diagnosing battery cell deterioration according to an embodiment of the present disclosure may include a memory 110 that stores a frequency distribution table and a processor 120 that diagnoses battery cell deterioration based on the frequency distribution table.

The processor 120 may calculate or otherwise determine the cell voltage representative value for the battery pack 200 for which deterioration is to be diagnosed, may generate the frequency distribution table, in which the current change amount of each class section into which the voltage range of the battery cell is divided is expressed as a frequency, based on the battery cell voltage and current data corresponding to the charging or discharging of the battery pack 200, may and store the frequency distribution table in the memory 110. The processor 120 may also preprocess the frequency distribution table to obtain the valid data range, may calculate the sum of the frequencies for each battery cell by adding up the frequencies within the valid data range, may calculate the deterioration degree and the frequency value corresponding to the cell voltage representative value, and may diagnose the deterioration of a battery cell 210 based on the deterioration degree and the frequency value corresponding to the cell voltage representative value and the sum of the frequencies for each battery cell.

In an embodiment, when a battery cell deterioration diagnosis execution request is received while calculating the cell voltage representative value, the processor 120 may determine the cell deterioration diagnosis mode corresponding to the discharging or charging, calculate the cell voltage representative value for the battery pack 200, may store the cell voltage representative value at the starting time point in the memory 110, and may perform the discharging or charging of the battery pack 200 corresponding to the determined cell deterioration diagnosis mode.

In an embodiment, when a request to execute the battery cell 210 deterioration diagnosis is received, the processor 120 may recognize that the battery cell deterioration diagnosis is started when diagnostic equipment is connected to on-board diagnostics (OBD) of the vehicle.

In addition, when the cell deterioration mode is determined, the processor 120 may check whether the state of charge (SOC) of the battery pack 200 exceeds a reference value, may determine the cell deterioration diagnosis mode corresponding to discharging when the state of charge (SOC) of the battery pack 200 exceeds the reference value, and may determine the cell deterioration diagnosis mode corresponding to charging when the state of charge (SOC) of the battery pack 200 is equal to or less than the reference value.

For example, the processor 120 may determine the cell deterioration diagnosis mode corresponding to discharging when the SOC of the battery pack 200 exceeds approximately 20%, and may determine the cell deterioration diagnosis mode corresponding to charging when the SOC of the battery pack 200 is less than about 20%.

In addition, when calculating the cell voltage representative value, the processor 120 may check whether a specified rest period elapses after the cell deterioration diagnosis mode is determined, and may calculate the cell voltage representative value for the battery pack 200 after the specified rest period elapses.

For example, after a rest period of about 1 hour, the processor 120 may calculate the cell voltage representative value for the battery pack 200.

In addition, when calculating the cell voltage representative value, the processor 120 may obtain the cell voltage representative value using the formula Vnml=Vpack/Cell No (where Vnml is a cell voltage representative value of a battery pack, Vpack is a voltage of the battery pack, and Cell No is the number of cells in the battery pack).

In addition, when the frequency distribution table is generated while the discharging or charging of the battery pack 200 is performed, the processor 120 may obtain the voltage and current data for each battery cell corresponding to the discharging or charging of the battery pack 200 and may store the frequency distribution table in the memory 110. The processor 120 may perform a clustered frequency distribution by dividing a voltage range of the battery cell 210 into class sections of a preset size based on the voltage and current data of each battery cell, and may generate the frequency distribution table in which the current change amount of each class section for each battery cell is expressed as a frequency.

In an embodiment, the processor 120 may check whether a change in state of charge (ΔSOC) of the battery pack 200 exceeds a reference value when the voltage and current data for each battery cell are stored and may perform the clustered frequency distribution based on the voltage and current data for each battery cell when the change in the state of charge of the battery pack 200 exceeds the reference value. The processor 120 may re-obtain the voltage and current data for each battery cell corresponding to the charging or discharging of the battery pack 200 when the change in the state of charge of the battery pack is less than the reference value, and may re-store the voltage and current data in the memory 110.

For example, the processor 120 may perform the clustered frequency distribution based on the voltage and current data for each battery cell when the change in the state of charge (ΔSOC) of the battery pack 200 exceeds about 30%. The processor 120 may re-obtain the voltage and current data for each battery cell corresponding to the charging or discharging of the battery pack 200 when the change in the state of charge of the battery pack is less than about 30%, and may re-store the voltage and current data in the memory 110.

In addition, when performing the clustered frequency distribution, the processor 120 may perform the clustered frequency distribution by dividing the voltage range of the battery cell 210 into class sections of about 20 mV voltage.

Then, when the valid data range is obtained, the processor 120 may obtain a high-resolution valid data range by performing a non-clustered frequency distribution through a preprocess of removing a frequency of a first class section and a frequency of a last class section from the frequency distribution table.

In an embodiment, the processor 120 may remove voltage data at a time point when the discharging or charging starts, voltage data before the time point when the discharging or charging starts, voltage data at a time point when the discharging or charging ends, and voltage data after the time point when the discharging or charging ends, based on the voltage data for each battery cell. The processor 120 may obtain the high-resolution valid data range including voltage data from the time point at which the discharging or charging starts to the time point at which the discharging or charging ends.

In some cases, when obtaining the high-resolution valid data range, the processor 120 may recognize voltage data corresponding to discharging or charging, which does not include a rising edge or a falling edge, as low-resolution data, and may remove the low-resolution data to obtain the high-resolution valid data range including high-resolution data.

For example, when obtaining the high-resolution valid data range, the processor 120 may generate a data frame by checking the maximum voltage of each cell for all battery cells in a discharging start class, may check the minimum voltage among all battery cells having the maximum voltage, and may delete data below the minimum voltage from all battery cells having the maximum voltage.

In addition, the processor 120 may generate the data frame by checking the minimum voltage of each cell for all battery cells in a discharging termination class, may check the maximum voltage among all battery cells having the minimum voltage, and may delete data exceeding the maximum voltage from all battery cells having the minimum voltage.

In addition, the processor 120 may generate the data frame by checking the minimum voltage of each cell for all battery cells in the charging start class, may check the maximum voltage among all battery cells having the minimum voltage, and may delete data exceeding the maximum voltage from all battery cells having the minimum voltage.

In addition, the processor 120 may generate the data frame by checking the maximum voltage of each cell for all battery cells in a charging termination class, may check the maximum voltage among all battery cells having the minimum voltage, and may delete data below the minimum voltage from all battery cells having the maximum voltage.

In addition, the processor 120 may obtain a high-resolution valid data range including high-resolution data having voltage data of about 1 mV.

In addition, when the sum of frequencies is calculated, the processor 120 may integrate a plurality of classes within the valid data range into one class by adding up frequencies classified by class within the valid data range for each battery cell in order to obtain the sum of frequencies for each battery cell, and may store the sum in the memory 110.

In an embodiment, the processor 120 may store a representative current value corresponding to the deterioration degree of each battery cell in the memory 110 based on the sum of frequencies for each battery cell.

In addition, the processor 120 may check whether the specified rest period elapses after the sum of frequencies for each battery cell is stored, may calculate the cell voltage representative value for the battery pack 200 after the specified rest period elapses, and may store the cell voltage representative value at the end time point in the memory 110.

For example, after a rest period of about 1 hour, the processor 120 may calculate the cell voltage representative value for the battery pack 200.

In addition, when calculating the cell voltage representative value, the processor 120 may obtain the cell voltage representative value using the formula Vnml=Vpack/Cell No (where Vnml is a cell voltage representative value of a battery pack, Vpack is a voltage of the battery pack, and Cell No is the number of cells in the battery pack).

In an embodiment, when calculating the deterioration degree corresponding to the cell voltage representative value, the processor 120 may calculate the deterioration degree corresponding to the cell voltage representative value by using the formula SOH_nml=ΔSOC_msr/ΔSOC_rated (where SOH_nml is the deterioration degree of the cell voltage representative value, ΔSOC_msr is the absolute value of the amount of change in SOC, and ΔSOC_rated is the relative value of the amount of change in SOC).

In an embodiment, when diagnosing the deterioration of each battery cell, the processor 120 may calculate a deterioration degree of each battery cell through a proportional formula based on a deterioration degree and a frequency value corresponding to the cell voltage representative value and the sum of the frequencies of each battery cell, and may diagnose the deterioration of the battery cell based on the calculated deterioration degree of each battery cell.

In an embodiment, when calculating the deterioration degree for each battery cell, the processor 120 may calculate the deterioration degree of each battery cell based on the proportional formula of “deterioration degree of cell voltage representative value: frequency value of cell voltage representative value=deterioration degree of each battery cell: sum of frequencies of each battery cell”

In addition, the processor 120 may control the deterioration degree for each battery cell to be displayed on the display screen of an external device when the deterioration degree for each battery cell is calculated.

In addition, the processor 120 may generate a diagnosis result when diagnosing battery cell deterioration and provide the result to an external server for storage.

As described above, according to embodiments of the present disclosure, by generating the frequency distribution table in which the current change amount by class section that divides the voltage range of the battery cell is expressed as a frequency, obtaining the valid data range, and diagnosing battery cell deterioration based on the sum of the frequencies of each battery cell by adding up the frequencies within the valid data range, it is possible to precisely diagnose the deterioration status of each battery cell without damage to vehicle parts or additional labor in a system with low voltage resolution.

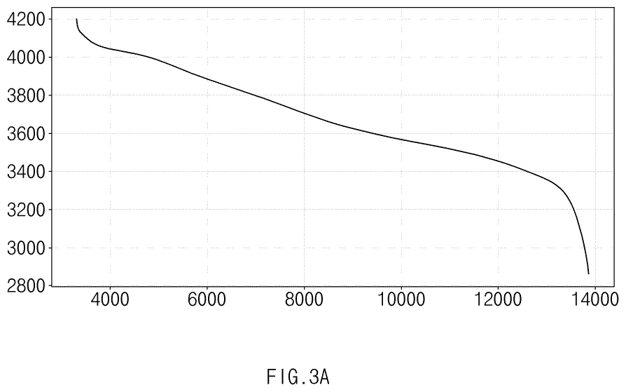

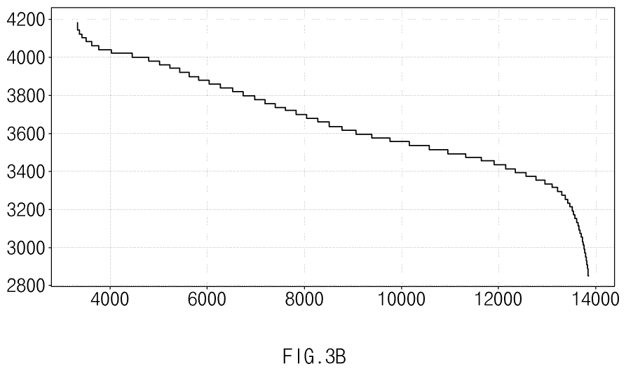

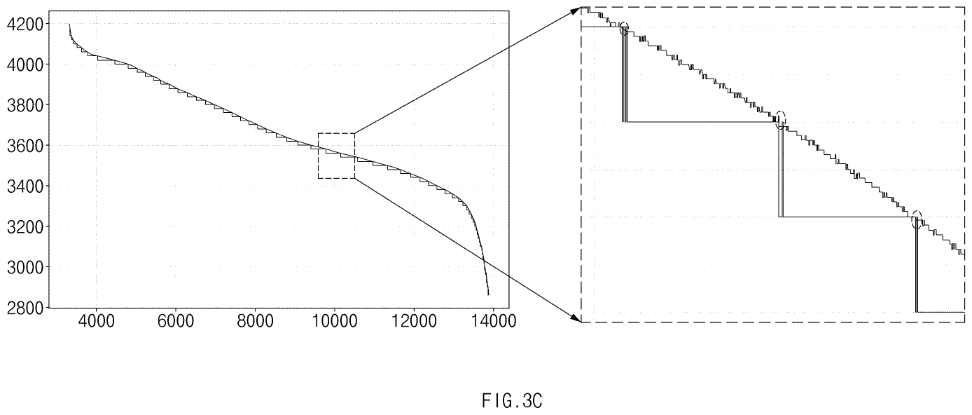

FIGS. 3A-C are diagrams illustrating a high-resolution data acquisition principle of an apparatus for diagnosing battery cell deterioration according to an embodiment of the present disclosure.

FIG. 3A is a graph illustrating a high-resolution voltage change of 1 mV used in on-board deterioration diagnosis in a vehicle. FIG. 3B is a graph illustrating a low-resolution voltage change of 20 mV used in off-board deterioration diagnosis outside the vehicle. FIG. 3C is a graph in which high-resolution voltage and low-resolution voltage are overlaid.

As illustrated in FIG. 3C, according to embodiments of the present disclosure, when off-board deterioration diagnosis is performed, it is possible to provide the same effect as using high-resolution voltage while using low-resolution voltage, so that the deterioration status may be precisely diagnosed for each battery cell without damaging vehicle parts or additional labor.

In general, on-board deterioration diagnosis inside a vehicle calculates the deterioration degree (SOH) using voltage data with a resolution of about 1 mV, and off-board deterioration diagnosis outside a vehicle uses voltage data with a resolution of about 20 mV, so the error is very large compared to on-board deterioration diagnosis.

For example, in the off-board voltage data, 3580 mV may include a range of 3580 to 3599 mV, and 3600 mV may include a range of 3600 to 3619 mV.

Therefore, when the actual cell voltage changes from 3599 mV to 3600 mV, the off-board sensing value may be displayed as changing from 3580 mV to 3600 mV.

In this case, the voltage change calculation error may be up to 19 mV, and data control may be impossible.

For example, the following are cases where the SOH is calculated lower than the actual value.

When a vehicle battery is discharged at about 10Ah and the voltage is about 3599 mV to 3480 mV so that a voltage difference of about 119 mV occurs, the on-board deterioration diagnosis may calculate the deterioration degree (SOH) for the voltage difference of about 119 mV and the current change amount of about 10 Ah when the discharge start voltage is 3599 mV and the discharge end voltage is 3480 mV, and the off-board deterioration diagnosis may calculate the deterioration degree (SOH) for the voltage difference of about 100 mV and the current change amount of about 10 Ah when the discharge start voltage is 3580 mV and the discharge end voltage is 3480 mV, so the capacity may be calculated to be lowered by about 19 mV.

As another example, the cases where the SOH is calculated higher than actual value are as follows.

When a vehicle battery is discharged at about 10 Ah and the voltage is about 3580 mV to 3499 mV so that a voltage difference of about 81 mV occurs, the on-board deterioration diagnosis may calculate the deterioration degree (SOH) for the voltage difference of about 81 mV and the current change amount of about 10 Ah when the discharge start voltage is 3580 mV and the discharge end voltage is 3499 mV, and the off-board deterioration diagnosis may calculate the deterioration degree (SOH) for the voltage difference of about 100 mV and the current change amount of about 10 Ah when the discharge start voltage is 3580 mV and the discharge end voltage is 3480 mV, so the capacity may be calculated to be about 19 mV higher.

Therefore, embodiments of the present disclosure may have an off-board voltage sensing resolution of about 20 mV, but a resolution equal to about 1 mV.

For example, because the time point at which the actual voltage crosses from 3561 mV to 3560 mV and the time point at which the off-board voltage crosses from 3580 mV to 3560 mV coincide, the point at which the value changes by about 20 mV based on the off-board voltage may have a resolution of about 1 mV.

In this case, according to embodiments of the present disclosure, by using only the values at the time point when the data values change during data collection, it is possible to achieve the same effect as using data with a resolution of about 1 mV.

Accordingly, according to the embodiments of the present disclosure, it is possible to achieve the same effect as using data on about 1 mV resolution when using only data of rising or falling edge points among data on about a resolution of 20 mV.

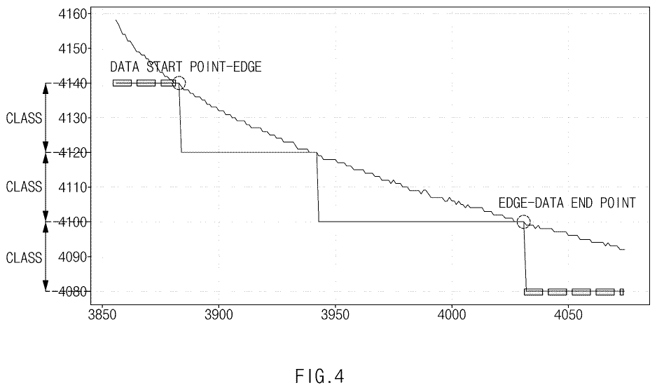

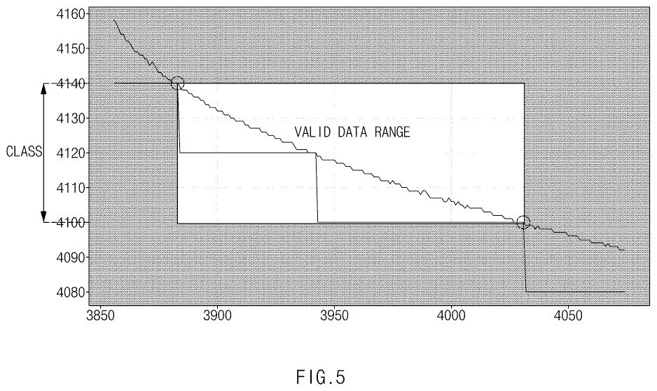

FIGS. 4 and 5 are diagrams illustrating a preprocessing process for obtaining high-resolution data by an apparatus for diagnosing battery cell deterioration according to an embodiment of the present disclosure.

As illustrated in FIG. 4, according to embodiments of the present disclosure, it is possible to preprocess data at the start and end time points of the discharging or charging, thereby removing data likely to be of low resolution.

For example, according to embodiments of the present disclosure, it is possible to remove errors included in low-resolution data by removing data that does not include rising or falling edges.

In this case, the data at both ends may not be considered as 1 mV unit data because no edge occurs.

According to embodiments of the present disclosure, it is possible to remove values before a change in data value occurs, thereby maintaining only high-resolution data.

Accordingly, according to embodiments the present disclosure, it is possible to obtain 1 mV resolution data by using the value at the moment when the voltage at the time point when the discharge starts moves to the next voltage, discarding the voltage at the time point when the discharge ends, and using the value at the moment when the voltage changes before the end.

According to embodiments of the present disclosure, it is possible to divide the voltage range by a class size of about 20 mV during a discharging section (or a charging section) for convenience of calculation, and generate a frequency distribution table in which the current change amount during each class section is the frequency.

In this case, according to embodiments of the present disclosure, it is possible to secure relative SOH information between cells.

As illustrated in FIG. 5, according to embodiments of the present disclosure, it is possible to calculate valid data used for SOH calculation of each cell through a non-clustered frequency distribution for data for which preprocessing is completed.

In addition, according to embodiments of the present disclosure, it is possible to calculate the sum of the frequencies of each cell by utilizing the sum of the frequencies within the valid data range.

As described above, according to embodiments of the present disclosure, it is possible to perform a clustered frequency distribution by dividing a voltage range of the battery cell into class sections of a preset size based on the voltage and current data of each battery cell, and generate a frequency distribution table in which a current change amount of each class section for each battery cell is expressed as a frequency.

In this case, according to embodiments of the present disclosure, when the clustered frequency distribution is performed, it is possible to perform the clustered frequency distribution by dividing the voltage range of the battery cell 210 into class sections of about 20 mV voltage.

In addition, according to embodiments of the present disclosure, it is possible to obtain a high-resolution valid data range by performing a non-clustered frequency distribution through a pre-process of removing a frequency of a first class section and a frequency of a last class from the frequency distribution table.

In this case, according to embodiments of the present disclosure, it is possible to remove voltage data at a time point when the discharging or charging starts, voltage data before the time point when the discharging or charging starts, voltage data at a time point when the discharging or charging ends, and voltage data after the time point when the discharging or charging ends, based on the voltage data for each battery cell, and obtain the high-resolution valid data range including voltage data from the time point at which the discharging or charging starts to the time point at which the discharging or charging ends.

In some cases, according to embodiments of the present disclosure, when obtaining the high-resolution valid data range, it is possible to recognize voltage data corresponding to the discharging or charging, which does not include a rising edge or a falling edge, as low-resolution data, and remove the low-resolution data to obtain the high-resolution valid data range including high-resolution data.

For example, according to embodiments of the present disclosure, when obtaining the high-resolution valid data range, it is possible to generate a data frame by checking the maximum voltage of each cell for all battery cells in a discharging start class, check the minimum voltage among all battery cells having the maximum voltage, and delete data below the minimum voltage from all battery cells having the maximum voltage.

In addition, according to embodiments of the present disclosure, it is possible to generate the data frame by checking the minimum voltage of each cell for all battery cells in a discharging termination class, check the maximum voltage among all battery cells having the minimum voltage, and delete data exceeding the maximum voltage from all battery cells having the minimum voltage.

In addition, according to embodiments of the present disclosure, it is possible to generate the data frame by checking the minimum voltage of each cell for all battery cells in the charging start class, check the maximum voltage among all battery cells having the minimum voltage, and delete data exceeding the maximum voltage from all battery cells having the minimum voltage.

In addition, according to embodiments of the present disclosure, it is possible to generate the data frame by checking the maximum voltage of each cell for all battery cells in a charging termination class, check the maximum voltage among all battery cells having the minimum voltage, and delete data below the minimum voltage from all battery cells having the maximum voltage.

In this case, according to embodiments of the present disclosure, it is possible to obtain a high-resolution valid data range including high-resolution data having voltage data of about 1 mV.

In this case, according to embodiments of the present disclosure, it is possible to integrate a plurality of classes within the valid data range into one class by adding up frequencies classified by class within the valid data range for each battery cell, and obtain and store the sum of frequencies for each battery cell.

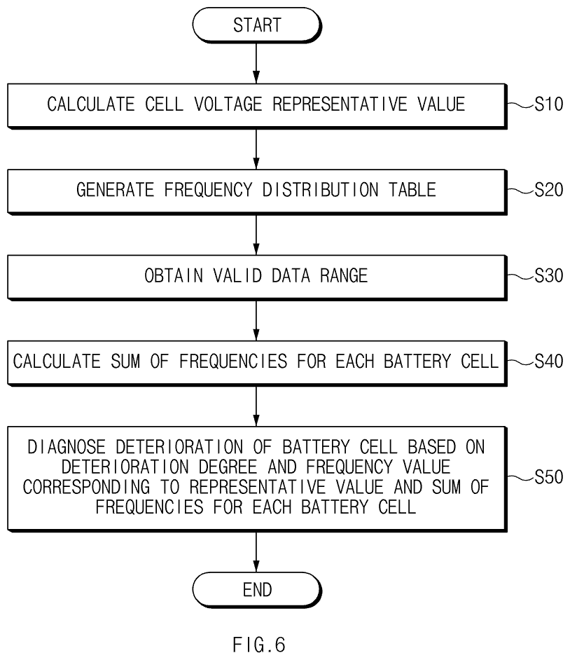

FIG. 6 is a flowchart illustrating a method of diagnosing battery cell deterioration according to an embodiment of the present disclosure.

As shown in FIG. 6, in an operation S10, the cell voltage representative value for a battery pack for which deterioration is to be diagnosed may be determined (e.g., may be calculated).

In an embodiment, when a battery cell deterioration diagnosis execution request is received, it is possible to determine the cell deterioration diagnosis mode corresponding to the discharging or charging, calculate the cell voltage representative value for the battery pack, store the cell voltage representative value at the starting time point, and perform the discharging or charging of the battery pack corresponding to the determined cell deterioration diagnosis mode

For example, according to an embodiment of the present disclosure, the cell voltage representative value may be calculated by using the formula Vnml=Vpack/Cell No (where Vnml is a cell voltage representative value of a battery pack, Vpack is a voltage of the battery pack, and Cell No is the number of cells in the battery pack).

In an operation S20, the frequency distribution table, in which the current change amount of each class section into which the voltage range of the battery cell is divided is expressed, as a frequency, based on the battery cell voltage and current data corresponding to the charging or discharging of the battery pack, may be generated.

According to an embodiment, when the discharging or charging of the battery pack is performed, the voltage and current data for each battery cell corresponding to the discharging or charging of the battery pack may be obtained and stored, the clustered frequency distribution may be performed by dividing a voltage range of the battery cell into class sections of a preset size based on the voltage and current data of each battery cell, and a frequency distribution table in which a current change amount of each class section for each battery cell is expressed as a frequency may be generated.

According to an embodiment, it may be checked whether a change in state of charge (ΔSOC) of the battery pack exceeds a reference value when the voltage and current data for each battery cell are stored. When the change in the state of charge of the battery pack exceeds the reference value, the clustered frequency distribution may be performed based on the voltage and current data for each battery cell. When the change in the state of charge of the battery pack is less than the reference value, the voltage and current data for each battery cell corresponding to the charging or discharging of the battery pack may be re-obtained and re-stored.

In an operation S30, the frequency distribution table may be preprocessed to obtain the valid data range.

According to an embodiment, it is possible to obtain a high-resolution valid data range by performing a non-clustered frequency distribution through a pre-process of removing a frequency of a first class section and a frequency of a last class from the frequency distribution table.

According to an embodiment, it is possible to remove voltage data at a time point when the discharging or charging starts, voltage data before the time point when the discharging or charging starts, voltage data at a time point when the discharging or charging ends, and voltage data after the time point when the discharging or charging ends, based on the voltage data for each battery cell, and the high-resolution valid data range including voltage data from the time point at which the discharging or charging starts to the time point at which the discharging or charging ends.

In an operation S40, the sum of the frequencies for each battery cell may be calculated by adding up the frequencies within the valid data range.

According to an embodiment, a plurality of classes within the valid data range may be integrated into one class by adding up frequencies classified by class within the valid data range for each battery cell, and the sum of frequencies for each battery cell may be calculated and stored.

In an operation S50, the deterioration degree and the frequency value corresponding to the cell voltage representative value may be calculated, and the deterioration of the battery cell may be diagnosed based on the deterioration degree and the frequency value corresponding to the cell voltage representative value and the sum of the frequencies for each battery cell.

According to an embodiment, a deterioration degree of each battery cell may be calculated through a proportional formula based on a deterioration degree and a frequency value corresponding to the cell voltage representative value and the sum of the frequencies of each battery cell, and diagnose the deterioration of the battery cell based on the calculated deterioration degree of each battery cell.

For example, according to an embodiment, the deterioration degree of each battery cell may be calculated based on the proportional formula of “deterioration degree of representative cell voltage value: frequency value of representative cell voltage value=deterioration degree of each battery cell: sum of frequencies of each battery cell”.

As described above, according to an embodiment of the present disclosure, by generating the frequency distribution table in which the current change amount by class section that divides the voltage range of the battery cell is expressed as a frequency, obtaining the valid data range, and diagnosing battery cell deterioration based on the sum of the frequencies of each battery cell by adding up the frequencies within the valid data range, it is possible to precisely diagnose the deterioration status of each battery cell without damage to vehicle parts or additional labor in a system with low voltage resolution.

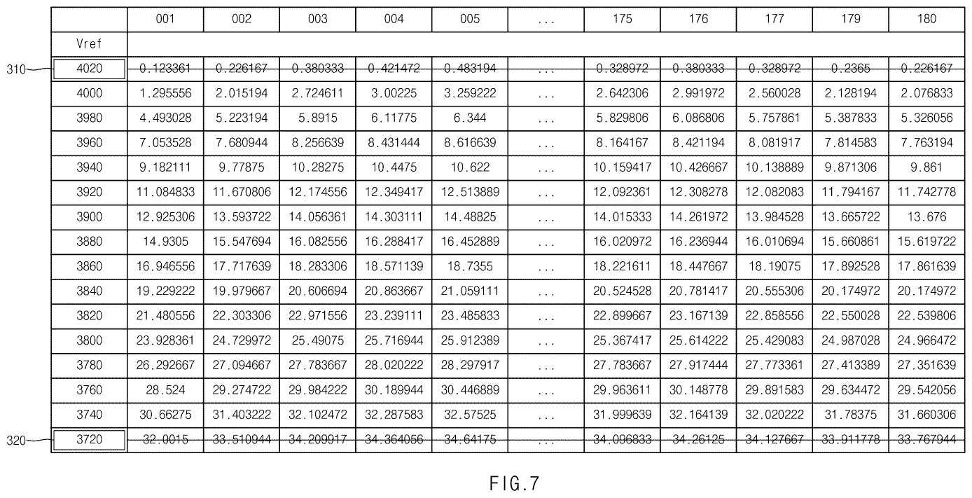

FIGS. 7-10 are diagrams illustrating a process of diagnosing battery cell deterioration based on a frequency distribution table by an apparatus for diagnosing battery cell deterioration according to an embodiment of the present disclosure.

As illustrated in FIG. 7, the clustered frequency distribution may be performed by dividing a voltage range of the battery cell into class sections of a preset size based on the voltage and current data of each battery cell, and a frequency distribution table in which a current change amount of each class section for each battery cell is expressed as a frequency may be generated.

In this case, according an embodiment, it is possible to obtain a high-resolution valid data range by performing a non-clustered frequency distribution through a pre-process of removing a frequency of a first class section 310 and a frequency of a last class 320 from the frequency distribution table.

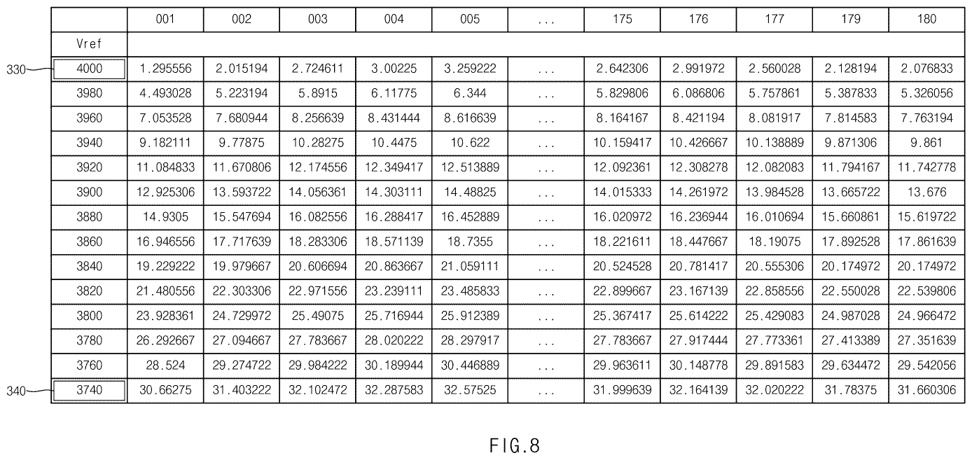

As illustrated in FIG. 8, according to an embodiment, the frequency distribution table may be preprocessed to obtain the valid data range.

In an embodiment, the valid data range may have a range of 4000 mV class 330 to 3740 mV class 340 including 1 mV resolution data.

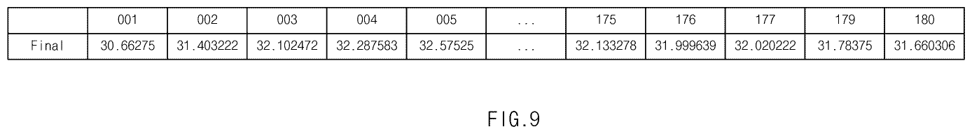

As illustrated in FIG. 9, according to an embodiment, the sum of the frequencies for each battery cell may be calculated by adding up the frequencies within the valid data range.

In this case, according to an embodiment, a plurality of classes within the valid data range may be integrated into one class by adding up frequencies classified by class within the valid data range for each battery cell, and the sum of frequencies for each battery cell may be calculated and stored.

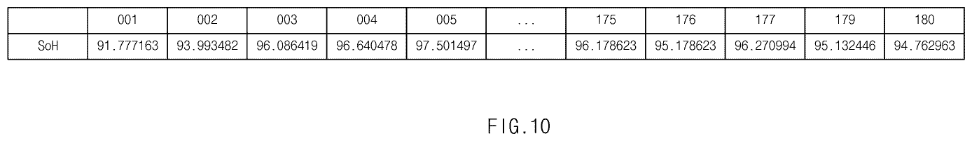

As illustrated in FIG. 10, according to an embodiment, the battery cell deterioration degree (SOH) may be calculated based on the sum of frequencies of each battery cell.

For example, according to an embodiment, the deterioration degree of each battery cell may be calculated based on the proportional formula of “deterioration degree of representative cell voltage value: frequency value of representative cell voltage value=deterioration degree of each battery cell: sum of frequencies of each battery cell”.

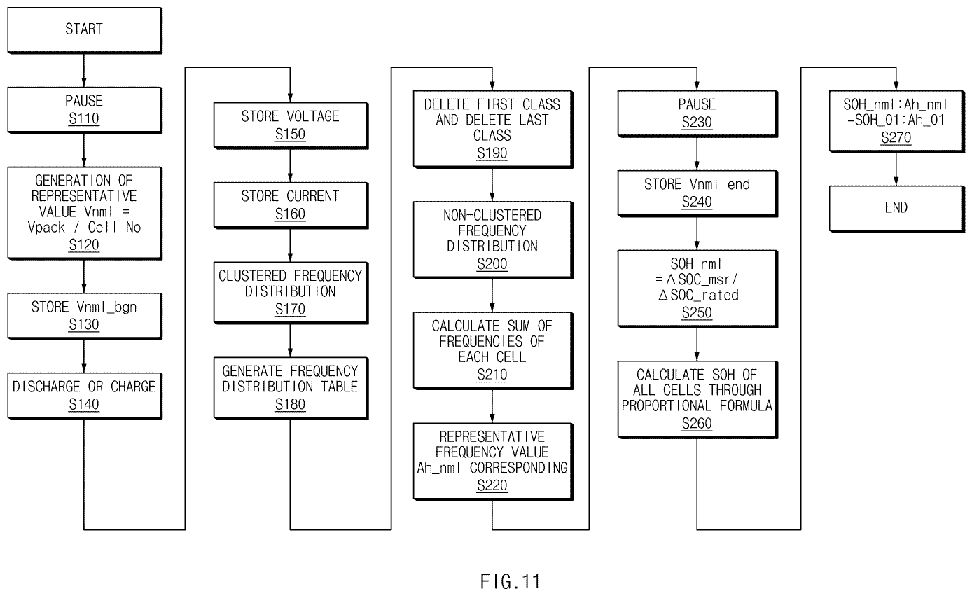

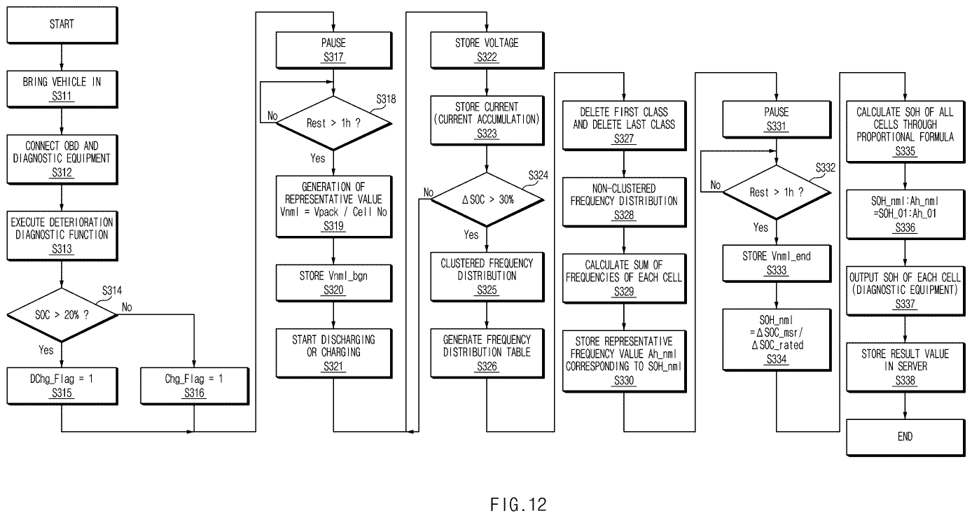

FIGS. 11 and 12 are flowcharts illustrating in more detail a method of diagnosing vehicle battery cell deterioration according to one embodiment of the present disclosure.

As illustrated in FIG. 11, in an operation S110, when a battery cell deterioration diagnosis execution request is received, a specified rest period may be provided.

In an operation S120, according to the present disclosure, the cell voltage representative value for the battery pack may be calculated after the specified rest period elapses.

According to an embodiment, the cell voltage representative value may be calculated by using the formula Vnml=Vpack/Cell No (where Vnml is a cell voltage representative value of a battery pack, Vpack is a voltage of the battery pack, and Cell No is the number of cells in the battery pack).

In an operation S130, when the cell voltage representative value for the battery pack is calculated, the cell voltage representative value at the starting time point may be stored in a memory.

In an operation S140, according to the present disclosure, discharging or charging of the battery pack may be performed.

In operations S150 and S160, when the discharging or charging of the battery pack is performed, the voltage and current data for each battery cell corresponding to the discharging or charging of the battery pack may be obtained and stored.

In an operation S170, a clustered frequency distribution may be performed by dividing a voltage range of the battery cell into class sections of a preset size based on the voltage and current data of each battery cell. In an operation S180, the frequency distribution table in which the current change amount of each class section for each battery cell is expressed as a frequency may be generated.

In operations S190 and S200, a high-resolution valid data range may be obtained by performing a non-clustered frequency distribution through a pre-process of removing a frequency of a first class section and a frequency of a last class from the frequency distribution table.

In an operation S210, a plurality of classes within the valid data range may be integrated into one class by adding up frequencies classified by class within the valid data range for each battery cell, and the sum of frequencies for each battery cell may be calculated.

In an operation S220, the representative current value corresponding to the deterioration degree of each battery cell based on the sum of frequencies for each battery cell may be stored.

In an operation S230, when the sum of frequencies for each battery cell is stored, a specified rest period may be provided.

In an operation S240, the cell voltage representative value for the battery pack may be calculated after the specified rest period elapses, and the cell voltage representative value at the end time point may be stored.

In an operation S250, the deterioration degree corresponding to the cell voltage representative value may be calculated by using the formula SOH_nml=ΔSOC_msr/ΔSOC_rated (where SOH_nml is the deterioration degree of the cell voltage representative value, ΔSOC_msr is the absolute value of the amount of change in SOC, and ΔSOC_rated is the relative value of the amount of change in SOC).

In an operation S260, a deterioration degree of each battery cell may be calculated through a proportional formula based on a deterioration degree and a frequency value corresponding to the cell voltage representative value and the sum of the frequencies of each battery cell.

In an operation S270, the deterioration degree of each battery cell may be calculated based on the proportional formula of “deterioration degree of representative cell voltage value: frequency value of representative cell voltage value=deterioration degree of each battery cell: sum of frequencies of each battery cell”.

FIG. 12 is a flowchart illustrating in more detail a method of diagnosing battery cell deterioration of a vehicle brought in.

As illustrated in FIG. 12, according to the present disclosure, when the vehicle is brought in and the diagnostic equipment is connected to the OBD of the vehicle brought in, in operations S311, S312 and S313, it may be recognized that the battery cell deterioration diagnosis is started.

Then, according to the present disclosure, when it is recognized that the battery cell deterioration diagnosis is started, in S314, it may be checked whether the state of charge of the battery pack exceeds a reference value. When the state of charge of the battery pack exceeds the reference value, in S315, the cell deterioration diagnosis mode corresponding to discharging may be determined. When the state of charge (SOC) of the battery pack is equal to or less than the reference value, in S316, the cell deterioration diagnosis mode corresponding to charging may be determined.

For example, according to an embodiment, when the state of charge of the battery pack exceeds about 20%, a flag may be assigned to the cell deterioration diagnosis mode corresponding to discharging, and when the state of charge (SOC) of the battery pack is equal to or less than about 20%, a flag may be assigned to the cell deterioration diagnosis mode corresponding to charging.

In an operation S317, when the cell deterioration diagnosis mode is determined, a specified rest period may be provided.

In an operation S318, it may be checked whether a specified rest period elapses.

According to an embodiment, when a rest period of about 1 hour elapses, the cell voltage representative value for the battery pack may be calculated.

In an operation S319, after a rest period of about 1 hour, the cell voltage representative value for the battery pack may be calculated.

According to an embodiment, the cell voltage representative value may be calculated by using the formula Vnml=Vpack/Cell No (where Vnml is a cell voltage representative value of a battery pack, Vpack is a voltage of the battery pack, and Cell No is the number of cells in the battery pack).

In an operation S320, when the cell voltage representative value for the battery pack is calculated, the cell voltage representative value at the starting time point may be stored.

In an operation S321, discharging or charging of the battery pack may be performed.

In operations S322 and S323, when the discharging or charging of the battery pack is performed, the voltage and current data for each battery cell corresponding to the discharging or charging of the battery pack may be obtained and stored.

In an operation S324, it may be checked whether a change in state of charge (ΔSOC) of the battery pack exceeds a reference value when the voltage and current data for each battery cell are stored.

When the change in the state of charge of the battery pack exceeds the reference value, the clustered frequency distribution may be performed based on the voltage and current data for each battery cell in an operation S325. On the other hand, when the change in the state of charge of the battery pack is less than the reference value, the voltage and current data for each battery cell corresponding to the charging or discharging of the battery pack may be re-obtained and re-stored in an operation S322.

According to an embodiment, the clustered frequency distribution may be performed based on the voltage and current data for each battery cell when the change in the state of charge (ΔSOC) of the battery pack exceeds about 30%, and the voltage and current data for each battery cell corresponding to the charging or discharging of the battery pack may be re-obtained and re-stored when the change in the state of charge of the battery pack is less than about 30%.

In an operation S325, a clustered frequency distribution may be performed by dividing a voltage range of the battery cell into class sections of a preset size based on the voltage and current data of each battery cell. In an operation S326, a frequency distribution table in which a current change amount of each class section for each battery cell is expressed as a frequency may be generated.

In operations S327 and S328, a high-resolution valid data range may be obtained by performing a non-clustered frequency distribution through a pre-process of removing a frequency of a first class section and a frequency of a last class from the frequency distribution table.

In an operation S329, a plurality of classes within the valid data range may be integrated into one class by adding up frequencies classified by class within the valid data range for each battery cell, and the sum of frequencies for each battery cell may be obtained.

In an operation S330, the representative current value corresponding to the deterioration degree of each battery cell based on the sum of frequencies for each battery cell may be stored.

In an operation S331, when the sum of frequencies for each battery cell is stored, a specified rest period may be provided.

In an operation S332, it may be checked whether a specified rest period elapses.

According to an embodiment, when a rest period of about 1 hour elapses, the cell voltage representative value for the battery pack may be calculated.

According to an embodiment, the cell voltage representative value may be calculated by using the formula Vnml=Vpack/Cell No (where Vnml is a cell voltage representative value of a battery pack, Vpack is a voltage of the battery pack, and Cell No is the number of cells in the battery pack).

In an operation S333, when the cell voltage representative value for the battery pack is calculated, the cell voltage representative value at the end time point may be stored.

In an operation S334, the deterioration degree corresponding to the cell voltage representative value may be calculated by using the formula SOH_nml =ΔSOC_msr/ΔSOC_rated (where SOH_nml is the deterioration degree of the cell voltage representative value, ΔSOC_msr is the absolute value of the amount of change in SOC, and ΔSOC_rated is the relative value of the amount of change in SOC).

In an operation S335, a deterioration degree of each battery cell may be calculated through a proportional formula based on a deterioration degree and a frequency value corresponding to the cell voltage representative value and the sum of the frequencies of each battery cell.

In an operation S336, the deterioration degree of each battery cell may be calculated based on the proportional formula of “deterioration degree of representative cell voltage value: frequency value of representative cell voltage value=deterioration degree of each battery cell: sum of frequencies of each battery cell”.

In an operation S337, when the deterioration degree for each battery cell is calculated, the deterioration degree for each battery cell may be controlled to be displayed on the display screen of an external device.

In an operation S338, when the battery cell deterioration is diagnosed, the diagnosis result may be generated and the diagnosis result may be provided to an external server for storage.

As described above, according to embodiments of the present disclosure, by generating the frequency distribution table in which the current change amount by class section that divides the voltage range of the battery cell is expressed as a frequency, obtaining the valid data range, and diagnosing battery cell deterioration based on the sum of the frequencies of each battery cell by adding up the frequencies within the valid data range, it is possible to precisely diagnose the deterioration status of each battery cell without damage to vehicle parts or additional labor in a system with low voltage resolution.

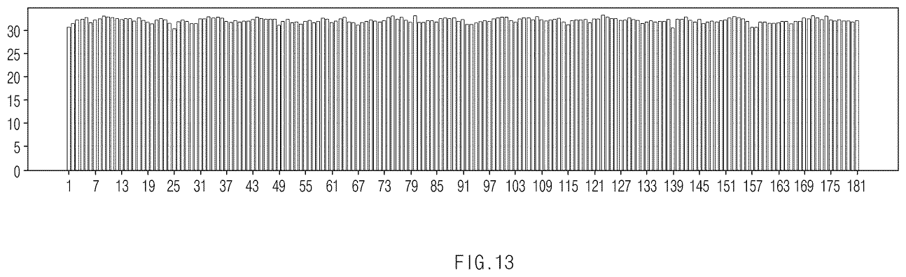

FIGS. 13-15 are graphs illustrating the results of diagnosing vehicle battery cell deterioration according to an embodiment of the present disclosure.

FIG. 13 is a graph illustrating the sum of the frequencies included within a voltage resolution valid data range.

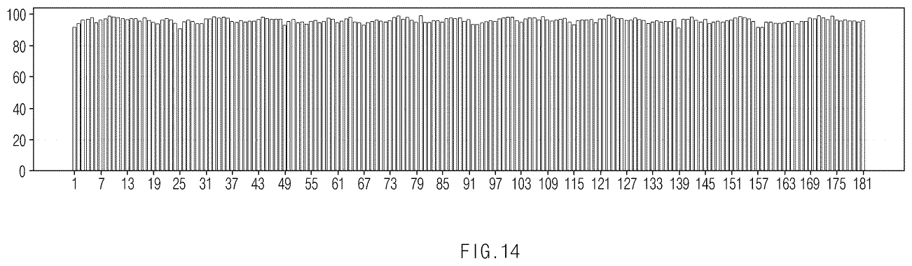

FIG. 14 is a graph in which the sum of frequencies is converted into the SOH value, and the relative current capacity value of FIG. 13 is converted into the absolute value.

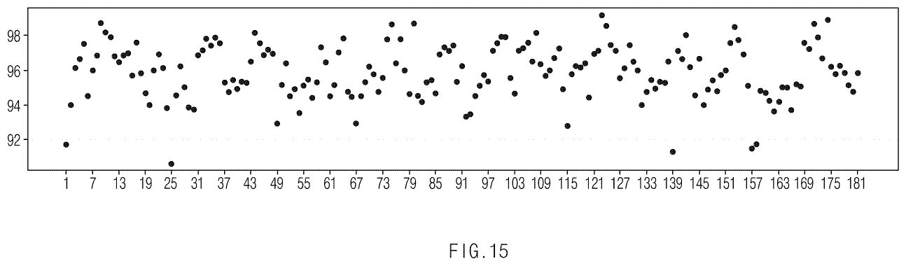

FIG. 15 is a diagram that expresses the graph of FIG. 14 as a scatter graph, as SOH data of each cell.

As illustrated in FIGS. 13-15, according to embodiments of the present disclosure, in a system with low voltage resolution, the deterioration state may be precisely diagnosed for each battery cell without damage to vehicle components or additional labor, and the diagnosis results may be compared for each battery cell and provided in a visual format, thereby allowing users to easily recognize it to provide user convenience.

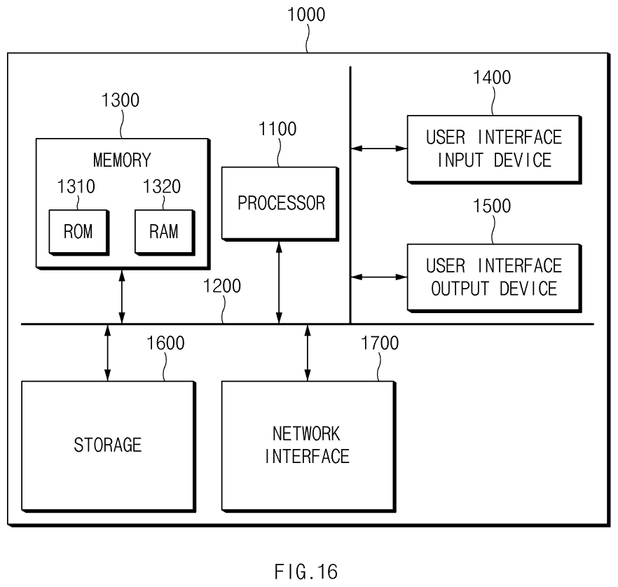

FIG. 16 is a block diagram illustrating a computing system of a vehicle according to an embodiment of the present disclosure.

Referring to FIG. 16, a computing system 1000 may include at least one processor 1100, a memory 1300, a user interface input device 1400, a user interface output device 1500, storage 1600, and a network interface 1700 connected through a bus 1200.

The processor 1100 may be a central processing unit (CPU) or a semiconductor device that processes instructions stored in the memory 1300 and/or the storage 1600. The memory 1300 and the storage 1600 may include various volatile or nonvolatile storage media. For example, the memory 1300 may include a read only memory (ROM) and a random access memory (RAM).

Accordingly, the processes of the method or algorithm described in relation to the embodiments of the present disclosure may be implemented directly by hardware executed by the processor 1100, a software module, or a combination thereof. The software module may reside in a storage medium (i.e., the memory 1300 and/or the storage 1600), such as a RAM memory, a flash memory, a ROM memory, an EPROM memory, an EEPROM memory, a register, a hard disk, a detachable disk, or a CD-ROM.

The storage medium is coupled to the processor 1100, and the processor 1100 may read information from the storage medium and may write information in the storage medium. In another method, the storage medium may be integrated with the processor 1100. The processor and the storage medium may reside in an application specific integrated circuit (ASIC). The ASIC may reside in a user terminal. In another example, the processor and the storage medium may reside in the user terminal as an individual component.

According to embodiments of the present disclosure, by generating a frequency distribution table in which a current change amount by class section that divides the voltage range of a battery cell is expressed as a frequency, obtaining a valid data range, and diagnosing battery cell deterioration based on the sum of frequencies of each battery cell by adding up the frequencies within the valid data range, it is possible to precisely diagnose the deterioration status of each battery cell without damage to vehicle components or additional labor even in a system with low voltage resolution.

In addition, various effects that are directly or indirectly understood through the present disclosure may be provided.

Although several embodiments of the present disclosure have been described for illustrative purposes, those having ordinary skill in the art should appreciate that various modifications, additions and substitutions are possible, without departing from the scope and spirit of the disclosure.

Therefore, the embodiments described in the present disclosure are provided for the sake of descriptions, not limiting the technical concepts of the present disclosure, and it should be understood that such embodiments are not intended to limit the scope of the technical concepts of the present disclosure. The protection scope of the present disclosure should be understood by the claims below, and all the technical concepts within the equivalent scopes should be interpreted to be within the scope of the right of the present disclosure.

What is claimed is:

1. An apparatus for diagnosing battery cell deterioration, the apparatus comprising:
a memory configured to store a frequency distribution table; and
a processor configured to diagnose the battery cell deterioration based on the frequency distribution table,
wherein the processor is configured to:
determine a cell voltage representative value for a battery pack for which deterioration is to be diagnosed,
generate the frequency distribution table based on battery cell voltage and current data corresponding to charging or discharging of the battery pack,
store the frequency distribution table in the memory,
preprocess the frequency distribution table to obtain a valid data range, and
diagnose the battery cell deterioration based on a frequency within the valid data range.

2. The apparatus of claim 1, wherein the processor is configured to:
determine a cell deterioration diagnosis mode corresponding to discharging or charging when a battery cell deterioration diagnosis execution request is received while determining the cell voltage representative value;
calculate the cell voltage representative value for the battery pack;
store the cell voltage representative value at a starting time point in the memory; and
perform the discharging or charging of the battery pack corresponding to the determined cell deterioration diagnosis mode.

3. The apparatus of claim 2, wherein the processor is configured to calculate the cell voltage representative value according to
Vnml=Vpack/Cell No,
wherein
Vnml is the cell voltage representative value of the battery pack,
Vpack is a voltage of the battery pack, and
Cell No is a number of cells in the battery pack.

4. The apparatus of claim 1, wherein the processor is configured to:
obtain voltage and current data for each battery cell corresponding to the discharging or charging of the battery pack when generating the frequency distribution table and performing the discharging or charging of the battery pack;
store the voltage and current data in the memory;
perform a clustered frequency distribution by dividing a voltage range of the battery cell into class sections of a preset size based on the voltage and current data of each battery cell; and
generate a frequency distribution table in which a current change amount of each class section for each battery cell is expressed as a frequency.

5. The apparatus of claim 4, wherein the processor is configured to:
determine whether a change in state of charge (ΔSOC) of the battery pack exceeds a reference value when the voltage and current data for each battery cell are stored;
perform the clustered frequency distribution based on the voltage and current data for each battery cell based on determining that the change in the state of charge of the battery pack exceeds the reference value;
re-obtain the voltage and current data for each battery cell corresponding to the charging or discharging of the battery pack based on determining that the change in the state of charge of the battery pack is less than the reference value; and
re-store the voltage and current data in the memory.

6. The apparatus of claim 1, wherein the processor is configured to obtain a high-resolution valid data range by performing a non-clustered frequency distribution through a preprocess of removing a frequency of a first class section and a frequency of a last class from the frequency distribution table when obtaining the valid data range.

7. The apparatus of claim 6, wherein the processor is configured to:
remove voltage data at a time point when the discharging or charging starts, voltage data before the time point when the discharging or charging starts, voltage data at a time point when the discharging or charging ends, and voltage data after the time point when the discharging or charging ends, based on the voltage data for each battery cell; and
obtain the high-resolution valid data range including voltage data from the time point at which the discharging or charging starts to the time point at which the discharging or charging ends.

8. The apparatus of claim 1, wherein the processor is configured to:
integrate a plurality of classes within the valid data range into one class by adding up frequencies classified by class within the valid data range for each battery cell when diagnosing the deterioration of each battery cell; and
calculate a sum of the frequencies for each battery cell and store the sum in the memory.

9. The apparatus of claim 8, wherein the processor is configured to:
calculate a deterioration degree of each battery cell through a proportional formula based on a deterioration degree and a frequency value corresponding to the cell voltage representative value and the sum of the frequencies of each battery cell when diagnosing the deterioration of each battery cell; and
diagnose the deterioration of the battery cell based on the calculated deterioration degree of each battery cell.

10. The apparatus of claim 9, wherein the processor is configured to calculate the deterioration degree of each battery cell based on the proportional formula expressed as
deterioration degree of cell voltage representative value: frequency value of cell voltage representative value =deterioration degree of each battery cell: sum of frequencies of each battery cell,
when calculating the deterioration degree for each battery cell.

11. A method for diagnosing battery cell deterioration, the method comprising:
determining, by a processor, a cell voltage representative value for a battery pack for which deterioration is to be diagnosed;
generating, by the processor, a frequency distribution table based on battery cell voltage and current data corresponding to charging or discharging of the battery pack;
preprocessing the frequency distribution table to determine a valid data range; and
diagnosing the battery cell deterioration based on a frequency within the valid data range.

12. The method of claim 11, wherein determining the cell voltage representative value includes:
determining a cell deterioration diagnosis mode corresponding to the discharging or charging when a battery cell deterioration diagnosis execution request is received;
calculating the cell voltage representative value for the battery pack;
storing the cell voltage representative value at a starting time point in a memory; and
performing the discharging or charging of the battery pack corresponding to the determined cell deterioration diagnosis mode.

13. The method of claim 12, wherein calculating the cell voltage representative value includes calculating the cell voltage representative value according to
Vnml=Vpack/Cell No,
wherein
Vnml is the cell voltage representative value of the battery pack,
Vpack is a voltage of the battery pack, and
Cell No is a number of cells in the battery pack.

14. The method of claim 11, wherein generating the frequency distribution table includes:
obtaining and storing voltage and current data for each battery cell corresponding to the discharging or charging of the battery pack when the discharging or charging of the battery pack is performed;
performing a clustered frequency distribution by dividing a voltage range of the battery cell into class sections of a preset size based on the voltage and current data of each battery cell; and
generating a frequency distribution table in which a current change amount of each class section for each battery cell is expressed as a frequency.

15. The method of claim 14, wherein generating the frequency distribution table includes:
determining whether a change in state of charge (ΔSOC) of the battery pack exceeds a reference value when the voltage and current data for each battery cell are stored;
performing the clustered frequency distribution based on the voltage and current data for each battery cell based on determining that the change in the state of charge of the battery pack exceeds the reference value; and
re-obtaining and restoring the voltage and current data for each battery cell corresponding to the charging or discharging of the battery pack based on determining that the change in the state of charge of the battery pack is less than the reference value.

16. The method of claim 11, wherein preprocessing the frequency distribution table to determine the valid data range includes obtaining a high-resolution valid data range by performing a non-clustered frequency distribution through a preprocess of removing a frequency of a first class section and a frequency of a last class from the frequency distribution table.

17. The method of claim 16, wherein preprocessing the frequency distribution table to determine the valid data range includes:
removing voltage data at a time point when the discharging or charging starts, voltage data before the time point when the discharging or charging starts, voltage data at a time point when the discharging or charging ends, and voltage data after the time point when the discharging or charging ends, based on the voltage data for each battery cell; and
obtaining the high-resolution valid data range including voltage data from the time point at which the discharging or charging starts to the time point at which the discharging or charging ends.

18. The method of claim 11, wherein diagnosing the battery cell deterioration includes:
integrating a plurality of classes within the valid data range into one class by adding up frequencies classified by class within the valid data range for each battery cell; and
calculating and storing a sum of the frequencies for each battery cell.

19. The method of claim 18, wherein diagnosing the battery cell deterioration includes:
calculating a deterioration degree of each battery cell through a proportional formula based on a deterioration degree and a frequency value corresponding to the cell voltage representative value and the sum of the frequencies of each battery cell; and
diagnosing the deterioration of the battery cell based on the calculated deterioration degree of each battery cell.

20. The method of claim 19, wherein calculating the deterioration degree of each battery cell includes calculating the deterioration degree of each battery cell based on a proportional formula expressed as
deterioration degree of cell voltage representative value: Frequency value of cell voltage representative value=deterioration degree of each battery cell: sum of frequencies of each battery cell.
